(19) United States
(12) Patent Application Publication
(10) Pub. No.: US 2022/0166361 A1
(43) Pub. Date: May 26, 2022

(54) POWER CONVERTER, DRIVE, AND POWER STEERING DEVICE

(71) Applicant: Nidec Corporation, Kyoto (JP)

(72) Inventors: Yoshiaki YAMASHITA, Kyoto (JP); Hiromitsu OHASHI, Kyoto (JP)

(21) Appl. No.: 17/442,177

(22) PCT Filed: Feb. 18, 2020
(86) PCT No.: PCT/JP2020/006207

§ 371 Date: Sep. 23, 2021

(30) Foreign Application Priority Data
Mar. 28, 2019 (JP) 2019-063435

(51) Int. Cl. H02P 27/08; H02M 7/5387; H02M 7/00; H02K 11/33; H05K 7/20; B62D 5/04

(52) U.S. Cl. CPC H02P 27/08; H02M 7/53871; B62D 5/04; H02K 11/33; H05K 7/209; H02M 7/003

(57) ABSTRACT

A power converter that converts power from a power source and supplies the converted power to a motor includes an inverter connected to a winding of the motor and including switches that generate heat along with power control operation, and a substrate on which the switches are mounted. A first switch of the switches is mounted in a first region on the substrate, and a second switch that generates more heat than the first switch is mounted in a second region having a higher heat dissipation than a heat dissipation of the first region.

### CROSS REFERENCE TO RELATED APPLICATIONS

This is a U.S. national stage of application No. PCT/JP2020/006207, filed on Feb. 18, 2020, and priority under 35 U.S.C. § 119(a) and 35 U.S.C. § 365(b) is claimed from Japanese Patent Application No. 2019-063435, filed on Mar. 28, 2019, the entire disclosures of which are hereby incorporated herein by reference.

### 1. FIELD OF THE INVENTION

The present disclosure relates to a power converter, a drive, and a power steering device.

### 2. BACKGROUND

Conventionally, a drive system that drives a motor with an inverter is known. In such a drive system, since the inverter generates heat along with driving of the motor, a structure for heat dissipation has been proposed.

For example, there is a configuration in which, in a rotary electric machine (motor) control device that controls energization of a rotary electric machine having a plurality of sets of windings, power conversion circuits of a plurality of systems are provided corresponding to the sets of winding, and the thickness of a heat sink in a corresponding portion of a specific circuit is different from that of a normal circuit.

However, conventionally, it is assumed that a plurality of inverters and switching elements in the inverters are in the same energized state. No consideration is given to an efficient heat dissipation structure in the case where the heat generation amounts of the inverters and the switching elements in the inverters are different from each other.

### SUMMARY

A power converter according to a preferred embodiment of the present disclosure converts power from a power source and supplies the converted power to a motor. The power converter includes an inverter connected to a winding of the motor and including switches to generate heat along with power control operation, and a substrate on which the switches are mounted. A first switch of the switches is mounted in a first region on the substrate, and a second switch that generates more heat than the first switch is mounted in a second region having higher heat dissipation than heat dissipation of the first region.

Further, one example embodiment of a drive according to the present disclosure includes the power converter described above and a motor to which the power converted by the power converter is supplied.

Further, one example embodiment of a power steering device according to the present disclosure includes the power converter described above, a motor to which the power converted by the power converter is supplied, and a power steering mechanism that is by the motor.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a diagram schematically illustrating a block configuration of a motor drive assembly according to an example embodiment of the present disclosure.

FIG. 2 is a diagram schematically illustrating a circuit configuration of a motor drive assembly according to an example embodiment of the present disclosure.

FIG. 3 is a diagram illustrating current values of currents flowing through the coils of respective phases of a motor according to an example embodiment of the present disclosure.

FIG. 4 is a diagram schematically illustrating a state where a current flows from one end side to the other end side of a winding of a motor under Pulse Width Modulation (PWM) control and solid on/off operation according to an example embodiment of the present disclosure.

FIG. 5 is a diagram schematically illustrating a state where a current flows from the other end side to the one end side of a winding of the motor under the PWM control and the solid on/off operation.

FIG. 6 is a diagram illustrating a heat generation state of each of switching elements in a motor drive assembly according to an example embodiment of the present disclosure.

FIG. 7 is an exploded perspective view of a motor drive assembly according to an example embodiment of the present disclosure.

FIG. 8 is a schematic cross-sectional view of a motor drive assembly 1000 according to an example embodiment of the present disclosure.

FIG. 9 is a diagram schematically illustrating switching element mounting areas according to an example embodiment of the present disclosure.

FIG. 10 is a diagram schematically illustrating switching element mounting areas in a modification of an example embodiment of the present disclosure in which an arrangement of a first region and a second region is different.

FIG. 11 is a diagram illustrating a modification of an example embodiment of the present disclosure in which positions of low-heat generating switching elements and high-heat generating switching elements on a circuit are different.

FIG. 12 is a diagram schematically illustrating an example of switching element mounting areas in the modification illustrated in FIG. 11.

FIG. 13 is a diagram schematically illustrating another example of switching element mounting areas in the modification illustrated in FIG. 11.

FIG. 14 is a diagram illustrating an example of switching element mounting arrangement with respect to the first region and the second region constructed without depending on the heat dissipation structure.

FIG. 15 is a diagram illustrating another example of switching element mounting arrangement with respect to the first region and the second region constructed without depending on the heat dissipation structure.

FIG. 16 is a diagram schematically illustrating a configuration of an electric power steering device according to an example embodiment of the present disclosure.

### DETAILED DESCRIPTION

Hereinafter, example embodiments of power converters, drives, and power steering devices of the present disclosure will be described in detail with reference to the accompanying drawings. However, in order to avoid the following description from being unnecessarily redundant and to make it easier for those skilled in the art to understand, a detailed description more than necessary may be omitted. For example, a detailed description of a well-known item or a redundant description of substantially the same configuration may be omitted.

In the present specification, example embodiments of the present disclosure will be described by taking, as an example, a power converter that converts electric power from a power source and supplies it to a three-phase motor having three-phase (U-phase, V-phase, W-phase) windings (sometimes referred to as “coils”). However, a power converter that converts power from a power source and supplies it to an n-phase motor having n-phase (n is an integer of 4 or more) windings such as four-phase or five-phase is also within the scope of the present disclosure.

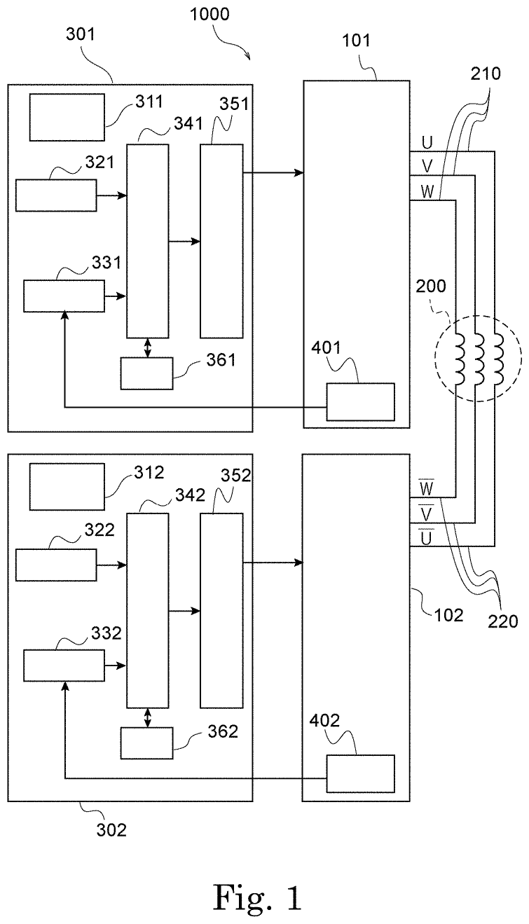

FIG. 1 is a diagram schematically illustrating a block configuration of a motor drive assembly 1000 according to the present example embodiment. The motor drive assembly 1000 includes inverters 101 and 102, a motor 200, and control circuits 301 and 302.

In the present specification, the motor drive assembly 1000 including the motor 200 as a component will be described. The motor drive assembly 1000 including the motor 200 corresponds to an example of a drive of the present disclosure. However, the motor drive assembly 1000 may be a device for driving the motor 200 in which the motor 200 is not included as a component. The motor drive assembly 1000 from which the motor 200 is omitted corresponds to an example of a power converter of the present disclosure.

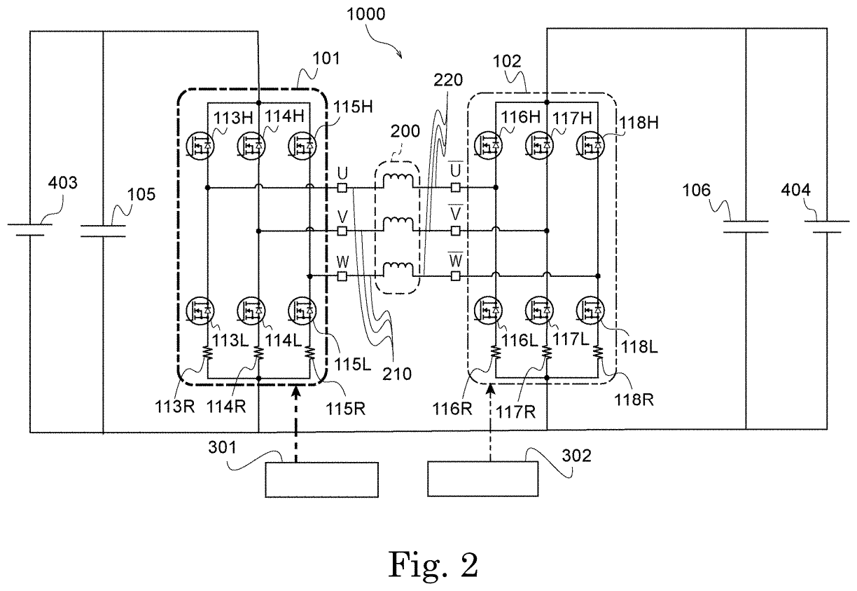

The motor drive assembly 1000 converts power from power sources (403 and 404 in FIG. 2) by the two inverters 101 and 102 and supplies the converted power to the motor 200. For example, the inverters 101 and 102 can convert DC power into three-phase AC power that is pseudo sine waves of U-phase, V-phase, and W-phase. The two inverters 101 and 102 include current sensors 401 and 402 respectively.

The motor 200 is, for example, a three-phase AC motor. The motor 200 has U-phase, V-phase and W-phase coils. The winding method of the coil is, for example, concentrated winding or distributed winding.

The first inverter 101 is connected to one ends 210 of the coils of the motor 200 and applies a drive voltage to the one ends 210, and the second inverter 102 is connected to the other ends 220 of the coils of the motor 200 and applies a drive voltage to the other ends 220. In the present specification, “connection” between parts (components) means electrical connection, unless otherwise specified.

The control circuits 301 and 302 respectively include microcontrollers 341 and 342 and the like, as described in detail later. The control circuits 301 and 302 control the driving current of the motor 200 on the basis of input signals from the current sensors 401 and 402 and angle sensors 321 and 322. Specifically, the control circuits 301 and 302 control the driving current of the motor 200 by controlling operations of the two inverters 101 and 102. As a method of controlling the driving current by the control circuits 301 and 302, for example, a control method selected from vector control and direct torque control (DTC) is used. A specific circuit configuration of the motor drive assembly 1000 will be described with reference to FIG. 2. FIG. 2 is a diagram schematically illustrating a circuit configuration of the motor drive assembly 1000 according to the present example embodiment.

The motor drive assembly 1000 is connected to a first power source 403 and a second power source 404 that are independent of each other. The power sources 403 and 404 generate a predetermined power source voltage (for example, 12V). As each of the power sources 403 and 404, for example, a DC power source is used. However, each of the power sources 403 and 404 may be an AC-DC converter or a DC-DC converter, or may be a battery (storage battery). In FIG. 2, the first power source 403 for the first inverter 101 and the second power source 404 for the second inverter 102 are illustrated as examples, but the motor drive assembly 1000 may be connected to a single power source shared by the first inverter 101 and the second inverter 102. Further, the motor drive assembly 1000 may have a power source inside.

The motor drive assembly 1000 includes a first system corresponding to one end 210 side of the motor 200 and a second system corresponding to the other end 220 side of the motor 200. The first system includes the first inverter 101 and the first control circuit 301. The second system includes the second inverter 102 and the second control circuit 302. The inverter 101 and the control circuit 301 of the first system are supplied with power from the first power source 403. The inverter 102 and the control circuit 302 of the second system are supplied with power from the second power source 404. Although the first control circuit 301 for the first inverter 101 and the second control circuit 302 for the second inverter 102 are illustrated in FIG. 2 as an example, the first inverter 101 and the second inverter 102 may be controlled by a single control circuit in the motor drive assembly 1000.

The first inverter 101 includes a bridge circuit having three legs. Each leg of the first inverter 101 includes a high-side switching element connected between the power source and the motor 200, and a low-side switching element connected between the motor 200 and the ground. Specifically, a U-phase leg includes a high-side switching element 113H and a low-side switching element 113L. A V-phase leg includes a high-side switching element 114H and a low-side switching element 114L. A W-phase leg includes a high-side switching element 115H and a low-side switching element 115L.

As a switching element, for example, a field effect transistor (MOSFET or the like) or an insulated gate bipolar transistor (IGBT or the like) is used. In addition, a power transistor of a material other than a silicon material may be used as a switching element. When the switching element is an IGBT, a diode (freewheel) is connected in antiparallel with the switching element.

For example, the first inverter 101 includes shunt resistors 113R, 114R, and 115R in the respective legs as the current sensor 401 (see FIG. 1) for detecting the current flowing through the windings of the respective phases of the U phase, the V phase, and the W phase. The current sensor 401 includes a current detection circuit (not illustrated) that detects a current flowing through each shunt resistor. For example, the shunt resistors can be connected between the low-side switching elements 113L, 114L, and 115L and the ground. The resistance value of each shunt resistor is, for example, about 0.5 mΩ to 1.0 mΩ.

The number of shunt resistors may be other than three. For example, two shunt resistors 113R and 114R for the U phase and the V phase, two shunt resistors 114R and 115R for the V phase and the W phase, or two shunt resistors 113R and 115R for the U phase and the W phase may be used. The number of shunt resistors to be used and the arrangement of the shunt resistors are appropriately determined in consideration of product cost, design specifications, and the like.

The second inverter 102 includes a bridge circuit having three legs. Each leg of the second inverter 102 includes a high-side switching element connected between the power source and the motor 200, and a low-side switching element connected between the motor 200 and the ground. Specifically, a U-phase leg includes a high-side switching element 116H and a low-side switching element 116L. A V-phase leg includes a high-side switching element 117H and a low-side switching element 117L. A W-phase leg includes a high-side switching element 118H and a low-side switching element 118L. Similarly to the first inverter 101, the second inverter 102 includes, for example, shunt resistors 116R, 117R, and 118R.

The motor drive assembly 1000 includes capacitors 105 and 106. Each of the capacitors 105 and 106 is a so-called smoothing capacitor which stabilizes the power source voltage and suppresses torque ripple by absorbing the recirculation current generated by the motor 200. Each of the capacitors 105 and 106 is, for example, an electrolytic capacitor, and the capacitance and the number of capacitors to be used are appropriately determined according to design specifications and the like.

FIG. 1 is referred to again. The control circuits 301 and 302 include, for example, power supply circuits 311 and 312, the angle sensors 321 and 322, input circuits 331 and 332, the microcontrollers 341 and 342, drive circuits 351 and 352, and ROMs 361 and 362. The control circuits 301 and 302 are connected to the inverters 101 and 102. Then, the first control circuit 301 controls the first inverter 101, and the second control circuit 302 controls the second inverter 102.

The control circuits 301 and 302 can realize closed-loop control by controlling the position (rotation angle) of a target rotor, rotation speed, current, and the like. The rotation speed is obtained by, for example, time-differentiating the rotation angle (rad), and is represented by a rotation speed (rpm) at which the rotor rotates per unit time (for example, one minute). The control circuits 301 and 302 can also control target motor torque. The control circuits 301 and 302 may include a torque sensor for torque control, but torque control is possible even if the torque sensor is omitted. In addition, a sensorless algorithm may be provided instead of the angle sensors 321 and 322. In the present example embodiment, torque control is performed by one of the two control circuits 301 and 302 (for example, the second control circuit 302). The power supply circuits 311 and 312 generate DC voltage (for example, 3 V, 5 V) necessary for the respective blocks in the control circuits 301 and 302.

The angle sensors 321 and 322 are, for example, resolvers or Hall ICs. The angle sensors 321 and 322 are also realized by a combination of an MR sensor having a magnetoresistive (MR) element and a sensor magnet. The angle sensors 321 and 322 detect the rotation angle of the rotor of the motor 200, and output rotation signals representing the detected rotation angle to the microcontrollers 341 and 342. Depending on the motor control approach (e.g., sensorless control), the angle sensors 321 and 322 may be omitted.

The input circuits 331 and 332 receive motor current values (hereinafter referred to as “actual current values”) detected by the current sensors 401 and 402. The input circuits 331 and 332 convert the levels of the actual current values into the input levels of the microcontrollers 341 and 342 as necessary, and output the actual current values to the microcontrollers 341 and 342. The input circuits 331 and 332 are analog-to-digital conversion circuits.

The microcontrollers 341 and 342 receive the rotation signals of the rotors detected by the angle sensors 321 and 322, and receive the actual current values output from the input circuits 331 and 332. Among the two microcontrollers 341 and 342, for example, the microcontroller 342 of the second control circuit 302 that performs torque control sets a target current value according to an actual current value, a rotation signal of the rotor, and the like, generates a PWM signal, and outputs the generated PWM signal to the drive circuit 352. The microcontroller 342 of the second control circuit 302 generates a PWM signal for controlling switching operation (turn-on or turn-off) of each switching element in the second inverter 102.

On the other hand, for example, the first control circuit 301 of the two microcontrollers 341 and 342 generates an on/off signal for controlling the switching operation of each switching element in the first inverter 101, and outputs it to the drive circuit 351. By the control with the on/off signal, the switching elements of the first inverter 101 maintain either the ON state or the OFF state during the time that the switching elements in the second inverter 102 perform the switching operation a plurality of times by the PWM control, and some of the plurality of switching elements in the first inverter 101 are turned on and the others are turned off. Such an operation in the switching elements of the first inverter 101 is hereinafter referred to as a solid on/off operation.

Sharing of the control in the two control circuits 301 and 302 and the two microcontrollers 341 and 342 and sharing of the operation in the two inverters 101 and 102 may be switched between the first system and the second system. However, for convenience of description, the following description will be made on the assumption that the solid on/off operation is performed on the first system side, and the PWM control is performed on the second system side.

The drive circuits 351 and 352 are typically gate drivers. The drive circuits 351 and 352 generate control signals (for example, gate control signals) for controlling switching operation of the respective switching elements in the first inverter 101 and the second inverter 102 according to the PWM signal and the on/off signal, and give the generated control signals to the respective switching elements. The microcontrollers 341 and 342 may have the functions of the drive circuits 351 and 352. In that case, the drive circuits 351 and 352 are omitted.

The ROMs 361 and 362 are, for example, writable memories (for example, PROMs), rewritable memories (for example, flash memories), or read-only memories. The ROMs 361 and 362 store a control program including a command group for causing the microcontrollers 341 and 342 to control the inverters 101 and 102 and the like. For example, the control program is temporarily expanded in a RAM (not illustrated) at the time of booting. Hereinafter, a specific example of the operation of the motor drive assembly 1000 will be described, and a specific example of the operation of the inverters 101 and 102 will be mainly described.

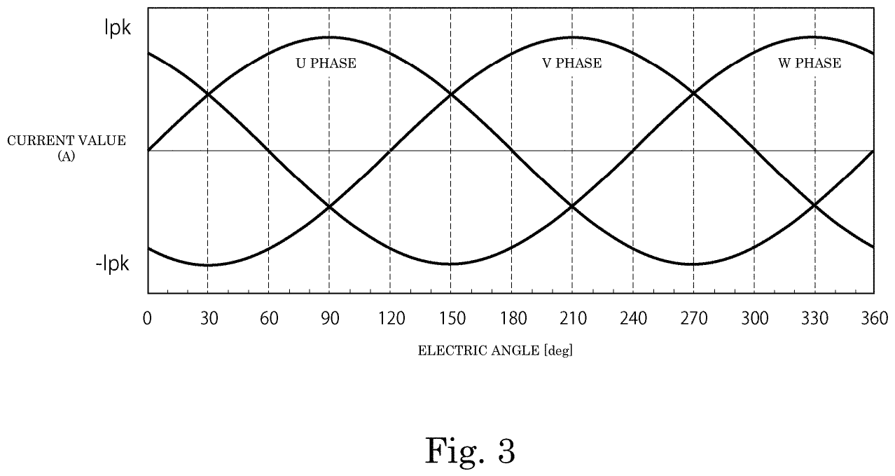

The control circuits 301 and 302 drive the motor 200 by performing three-phase energization control using the first inverter 101 and the second inverter 102. Specifically, the control circuits 301 and 302 perform three-phase energization control by switching control of the switching element of the first inverter 101 and the switching element of the second inverter 102. FIG. 3 is a diagram illustrating current values of currents flowing through the coils of the respective phases of the motor 200.

FIG. 3 illustrates current waveforms (sine waves) obtained by plotting the current values of currents flowing through the U-phase, V-phase, and W-phase coils of the motor 200 when the first inverter 101 and the second inverter 102 are controlled according to the three-phase energization control. The horizontal axis of FIG. 3 indicates the motor electric angle (deg), and the vertical axis indicates the current value (A). Iₚₖ represents a maximum current value (peak current value) of each phase. The inverters 101 and 102 can also drive the motor 200 using, for example, a square wave, besides the sine wave illustrated in FIG. 3.

The current waveform illustrated in FIG. 3 is generated when a voltage having a waveform corresponding to the current waveform is applied to the motor 200. The amplitude of the voltage waveform is generated when the switching element of the second inverter 102 performs switching at a high speed such as 20 kHz by the PWM control. In addition, the positive/negative of the voltage waveform is caused by switching between the on state and the off state in the solid on/off operation in each switching element of the first inverter 101 and switching of an element that performs switching by the PWM control among the switching elements of the second inverter 102.

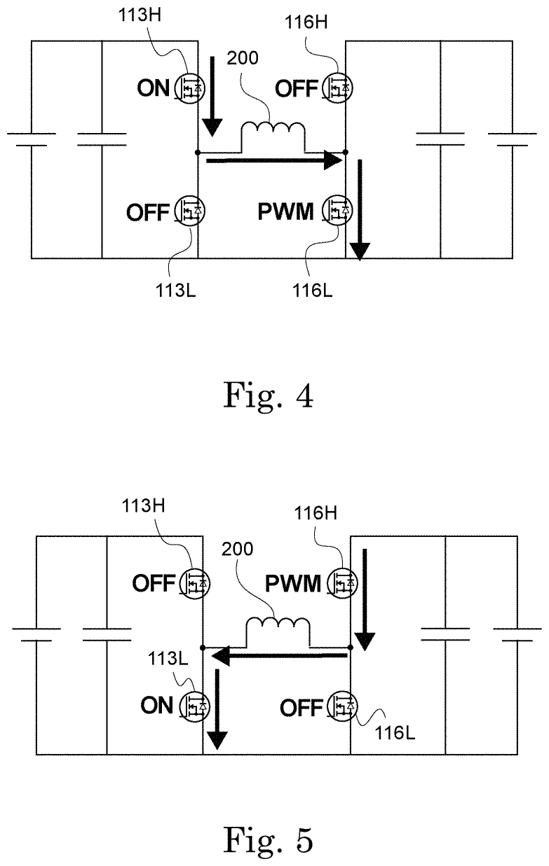

FIGS. 4 and 5 are diagrams schematically illustrating the switching operation under the PWM control and the solid on/off operation. FIG. 4 illustrates a state where the current flows from one end side to the other end side of a winding of the motor, and FIG. 5 illustrates a state where the current flows from the other end side to the one end side of a winding of the motor.

FIGS. 4 and 5 illustrate, for example, the U-phase leg among the legs of the inverters 101 and 102. As described above, the U-phase leg includes the high-side switching element 113H and the low-side switching element 113L on the first inverter 101 side and the high-side switching element 116H and the low-side switching element 116L on the second inverter 102 side.

The high-side switching element 113H and the low-side switching element 113L on the first inverter 101 side are not simultaneously turned on, and when one is turned on, the other is turned off. Similarly, the high-side switching element 116H and the low-side switching element 116L on the second inverter 102 side are not simultaneously turned on.

When the current flows from one end side to the other end side of the winding of the motor 200 as indicated by an arrow in FIG. 4, in the first inverter 101, the high-side switching element 113H is turned on, and the low-side switching element 113L is turned off. In the second inverter 102, the high-side switching element 116H is turned off, and the low-side switching element 116L performs the switching operation according to the PWM control.

When the current flows from the other end side to the one end side of the winding of the motor 200 as indicated by an arrow in FIG. 5, the high-side switching element 113H is turned off and the low-side switching element 113L is turned on in the first inverter 101. In the second inverter 102, the high-side switching element 116H performs the switching operation according to the PWM control, and the low-side switching element 116L is turned off.

For example, in the case where the current waveform illustrated in FIG. 3 is used, the state illustrated in FIG. 4 and the state illustrated in FIG. 5 are repeated. Each of the switching elements 113H, 113L, 116H, and 116L generates heat along with the switching operation for the power control. For this reason, the switching elements 116H and 116L of the second inverter 102 that frequently perform the switching operation according to the PWM control generate more heat than the switching elements 113H and 113L of the first inverter 101 that perform the solid on/off operation, as average heat generation during the normal operation.

As illustrated in FIG. 4, the high-side switching element 113H that is turned on in the solid on-off operation is connected to low-side switching element 116L via the winding of the motor 200, and a current controlled by switching of the low-side switching element 116L flows. In addition, as illustrated in FIG. 5, the low-side switching element 113L that is turned on by the solid on/off operation is connected to high-side switching element 116H via the winding of the motor 200, and a current controlled by switching of high-side switching element 116H flows. Since the switching operation is different between one side and the other side across the winding of the motor 200, sharing of heat generation between the switching elements is realized.

As compared with the case where both switching elements connected to both ends of the winding of the motor 200 frequently perform switching operation according to the PWM control in the conventional PWM control, in the present example embodiment, the solid on/off operation is performed on one side of the winding of the motor 200. Therefore, the amount of heat generated by the motor drive assembly 1000 is smaller than that in the conventional case.

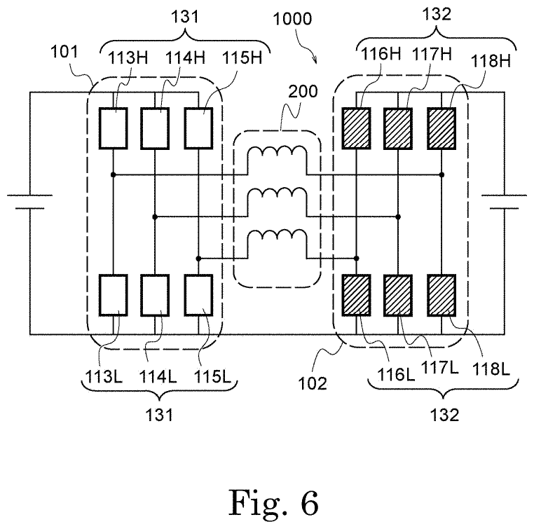

FIG. 6 is a diagram illustrating a heat generation state of each of the switching elements in the motor drive assembly 1000.

In the motor drive assembly 1000 of the present example embodiment, out of the two inverters 101 and 102 connected to both ends of the motor 200, six switching elements 116H, 117H, 118H, 116L, 117L, and 118L provided to the second inverter 102 are high-heat generating switching elements 132 indicated by hatching in the drawing that operate according to the PWM control. In addition, out of the two inverters 101 and 102, six switching elements 113H, 114H, 115H, 113L, 114L, and 115L provided to the first inverter 101 are low-heat generating switching elements 131 indicated by white blanks in the drawing that perform a solid on/off operation.

In other words, the low-heat generating switching elements 131 are provided to one of the first inverter 101 and the second inverter 102, and the high-heat generating switching elements 132 are provided to the other of them. As described above, in the motor drive assembly 1000 of the present example embodiment, heat generation is shared in units of inverters.

Furthermore, the motor drive assembly 1000 of the present example embodiment has a hardware structure with high heat dissipation efficiency in consideration that both the switching elements 132 with high heat generation and the switching elements 131 with low heat generation are included.

The reason why the amount of heat generated in the switching element is different is not only the case where the frequency of switching is different as described above, but also the case where the applied voltage is different, the case where the composition is different, the case where the resistance of the reflux diode is different, and the like. Even when the amount of heat generated in the switching element is different for any reason, a hardware structure with high heat dissipation efficiency described below can be applied.

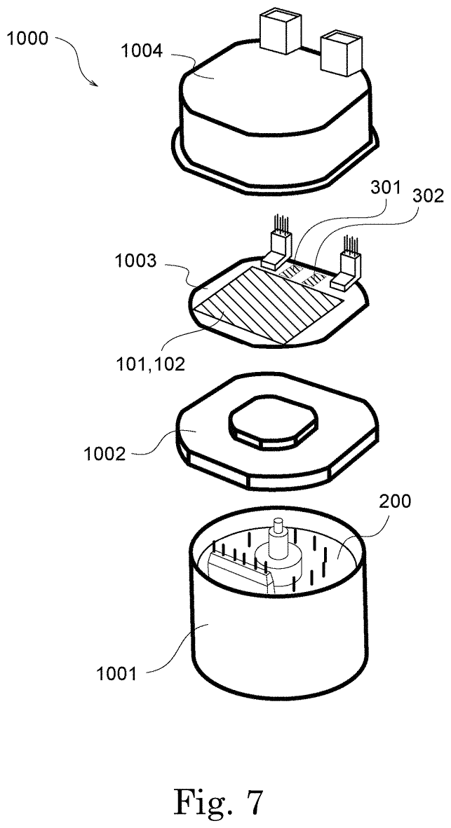

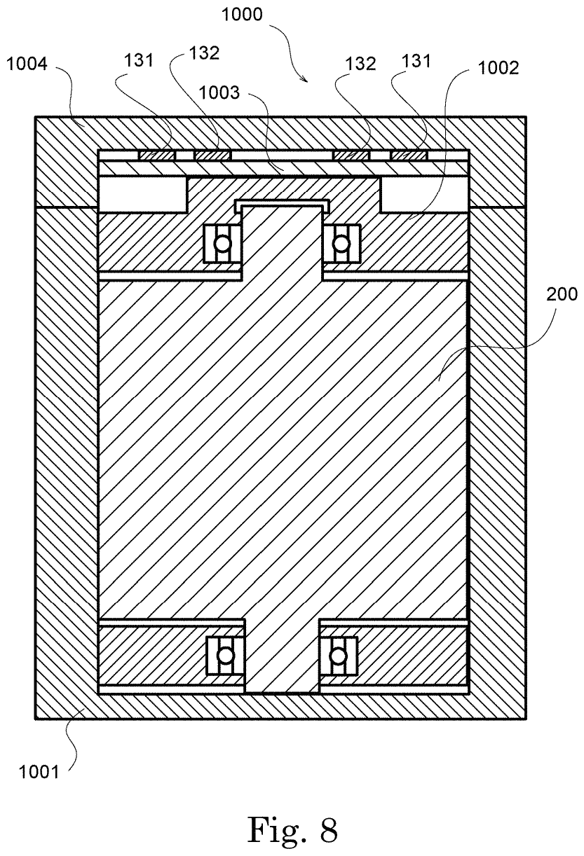

Hereinafter, the hardware configuration of the motor drive assembly 1000 will be described. FIG. 7 is an exploded perspective view of the motor drive assembly 1000, and FIG. 8 is a schematic cross-sectional view of the motor drive assembly 1000.

The motor drive assembly 1000 includes a lower housing 1001, the motor 200, a bearing holder 1002, a substrate 1003, and an upper housing 1004.

The lower housing 1001 and the upper housing 1004 house and integrate the motor 200, the bearing holder 1002, and the substrate 1003 therein. Thus, the motor drive assembly 1000 is assembled as a so-called electromechanical motor. The two inverters 101 and 102 and the two control circuits 301 and 302 for controlling the respective inverters 101 and 102 are mounted on the substrate 1003.

The upper housing 1004 also serves as a main heat sink that directly or indirectly contacts both the low-heat generating switching elements 131 and the high-heat generating switching elements 132 to dissipate heat from the entire switching elements 131 and 132. The main heat sink achieves efficient heat dissipation in the entire switching elements 131 and 132.

The bearing holder 1002 is a holder of a bearing that holds the rotation shaft of the motor 200 and, in the present example embodiment, the bearing holder also serves as a sub-heat sink that contacts a part of the substrate 1003 to promote heat dissipation. As a result, the first region and the second region having higher heat dissipation than that of the first region exist in the substrate 1003. The low-heat generating switching elements 131 is mounted in the first region, and the high-heat generating switching element 132 is mounted in the second region.

In other words, the sub-heat sink directly or indirectly contacts the high-heat generating switching element 132 mounted in the second region to dissipate heat, and promotes heat dissipation in the second region more than heat dissipation in the first region. The bearing holder 1002 also serving as a sub-heat sink contacts the back surface (the lower surface in the drawing) of the substrate 1003 to indirectly contact the switching element 132 mounted on the front surface (the upper surface in the drawing) of the substrate 1003 and dissipate heat.

In the present example embodiment, both the bearing holder 1002 and the upper housing 1004 also serve as a heat sink, but more generally, it is desirable that at least one of the housing that houses the motor 200 and the holder of the bearing that holds the rotation shaft of the motor 200 also serves as a heat sink that directly or indirectly contacts the switching element to dissipate heat. When at least one of the housing and the bearing holder also serves as a heat sink, it contributes to suppression of the number of components and space saving.

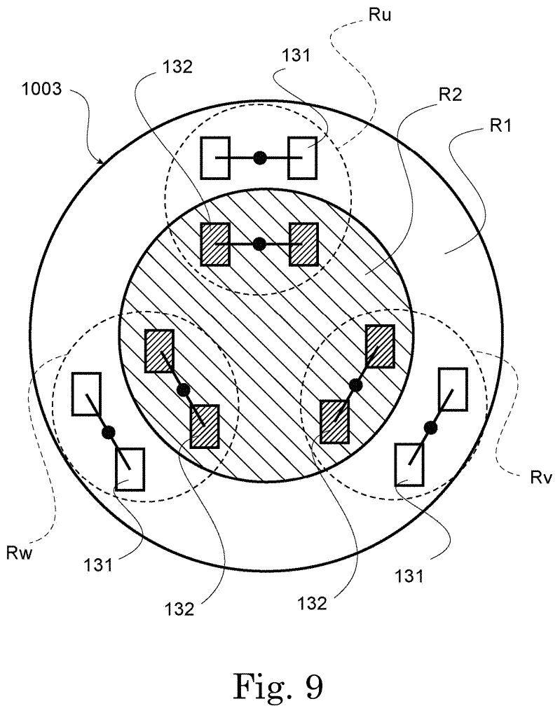

The sub-heat sink is an example of a heat dissipation structure that promotes heat dissipation in the second region more than heat dissipation in the first region, and is an example of a heat dissipation structure provided outside the substrate. As such a heat dissipation structure, in addition to the sub-heat sink, a structure in which the thickness and the material of the main heat sink are different between the first region and the second region, and a structure in which the thickness and the material of grease that mediates heat conduction between the main heat sink and the switching element are different between the first region and the second region can be considered. In addition, a structure in which the thickness and the material of the substrate are different between the first region and the second region is also considered as a heat dissipation structure that promotes heat dissipation in the second region more than heat dissipation in the first region, and in that case, it is an example of a heat dissipation structure provided inside the substrate. With such a heat dissipation structure, a desirable difference in heat dissipation is formed. In particular, when the sub-heat sink is used, a desirable difference in heat dissipation is easily formed. Next, specific examples of the arrangement of the first region and the second region and the mounting areas of the switching elements 131 and 132 will be described. FIG. 9 is a diagram schematically illustrates mounting areas of the switching elements 131 and 132.

FIG. 9 illustrates the surface of the substrate 1003. One region (for example, a region of a central portion) obtained by dividing a region on the substrate 1003 into the central portion and an edge portion is a second region R2 having high heat dissipation, and the other region (for example, a region of the edge portion) is a first region R1 having low heat dissipation. The low-heat generating switching element 131 is mounted in the first region R1, and the high-heat generating switching element 132 is mounted in the second region R2. By mounting each of the switching elements 131 and 132 in the regions R1 and R2 having heat dissipation according to the calorific value, high heat dissipation efficiency is realized. In particular, when the high-heat generating switching element 132 is a switching element that performs switching by the PWM control, heat generated along with the switching of the PWM control is efficiently dissipated. In addition, since the heat dissipation efficiency in the circuit on the substrate 1003 corresponding to a power converter is high, miniaturization and high output of the electromechanical motor corresponding to a drive are realized.

In the example illustrated in FIG. 9, the U-phase switching elements 131 and 132 are collectively mounted at an area Ru for the U phase, the V-phase switching elements 131 and 132 are collectively mounted at an area Rv for the V phase, and the W-phase switching elements 131 and 132 are collectively mounted at an area Rw for the W phase. Then, the phases are in isotropic mounting arrangement to each other. Since the first region R1 and the second region R2 are one region and the other region obtained by dividing the region on the substrate 1003 into the central portion and the edge portion, isotropic mounting arrangement as illustrated in FIG. 9 becomes possible.

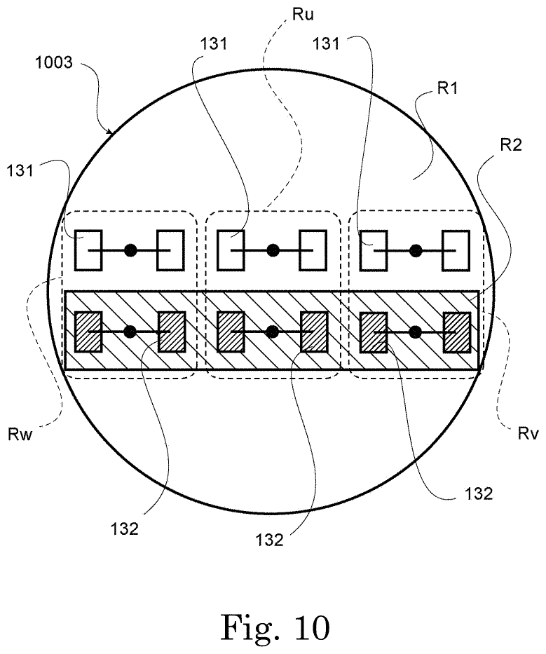

Modifications of the arrangement of the first region and the second region and the mounting areas of the switching elements 131 and 132 will be described below. FIG. 10 is a diagram schematically illustrating mounting areas of the switching elements 131 and 132 in a modification in which the arrangement of the first region and the second region is different.

In the modification illustrated in FIG. 10, the first region R1 and the second region R2 are one region and the other region obtained by dividing the region on the substrate 1003 by a linear boundary. The second region R2 of such a modification is formed by, for example, a rod-like sub-heat sink.

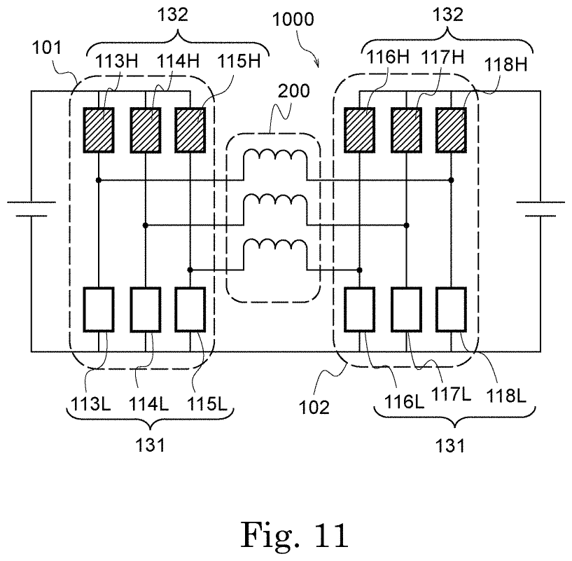

Furthermore, in the modification illustrated in FIG. 10, the switching elements 131 and 132 of the U, V, and W phases are collectively mounted for each phase in the three regions Ru, Rv, and Rw arranged along the boundary between the first region R1 and the second region R2. With such mounting, a symmetrical mounting arrangement about the boundary between the first region R1 and the second region R2 is possible. Next, a modification in which the position of the low-heat generating switching elements 131 are different from the positions of the high-heat generating switching elements 132 on the circuit will be described. FIG. 11 is a diagram illustrating a modification in which positions of the low-heat generating switching elements 131 are different from the positions of the high-heat generating switching elements 132 on the circuit.

In the modification illustrated in FIG. 11, the low-heat generating switching elements 131 are either of the high-side switching elements 113H, . . . , 118H or the low-side switching elements 113L, . . . , 118L (for example, low-side switching elements), and the high-heat generating switching elements 132 are the other thereof (for example, high-side switching elements). In the case of such a modification, heat generation of the switching elements is shared in each of the sides.

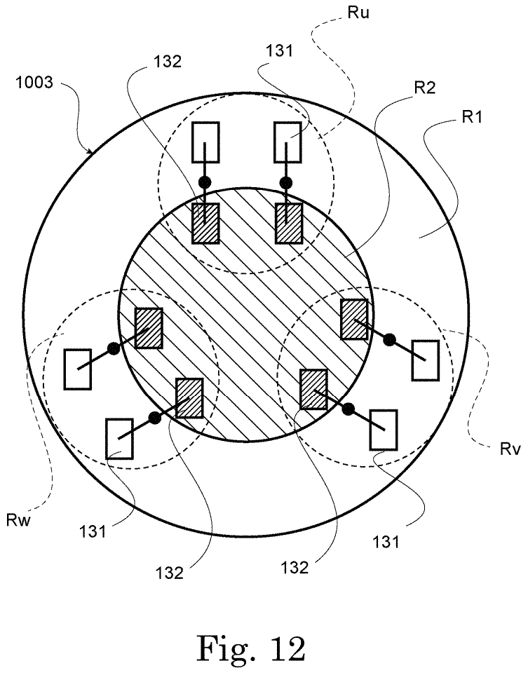

Also in the modification illustrated in FIG. 11, the low-heat generating switching element 131 performs solid on/off operation, and the high-heat generating switching element 132 performs switching operation according to the PWM control. In addition, also in this modification, the switching element 131 that performs solid on/off operation is connected to the high-heat generating switching element 132 via the winding of the motor 200, and a current controlled by switching of the high-heat generating switching element 132 flows. The mounting areas of the switching elements 131 and 132 in such a modification will be described below. FIG. 12 is a diagram schematically illustrating an example of mounting areas of the switching elements 131 and 132 in the modification illustrated in FIG. 11.

Also in the case illustrated in FIG. 12, as in the case illustrated in FIG. 9, one region (for example, a region of the central portion) obtained by dividing the region on the substrate 1003 into the central portion and the edge portion is the second region R2 having high heat dissipation, and the other region (for example, a region of the edge portion) is the first region R1 having low heat dissipation. The low-heat generating switching element 131 is mounted in the first region R1, and the high-heat generating switching element 132 is mounted in the second region R2.

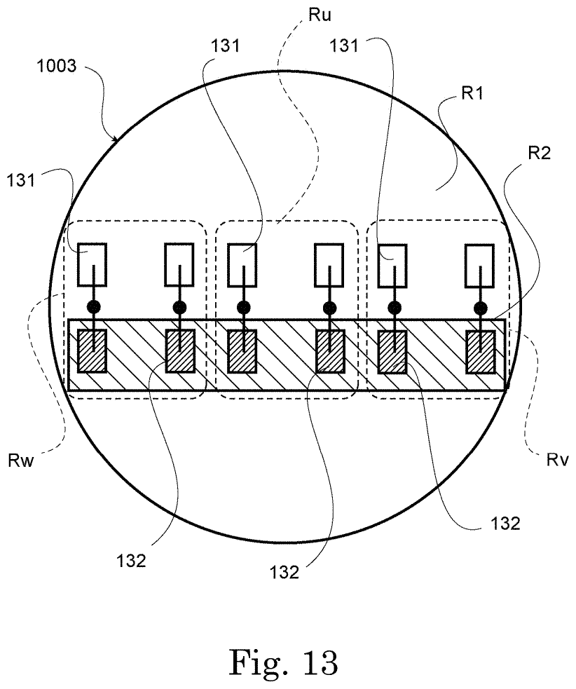

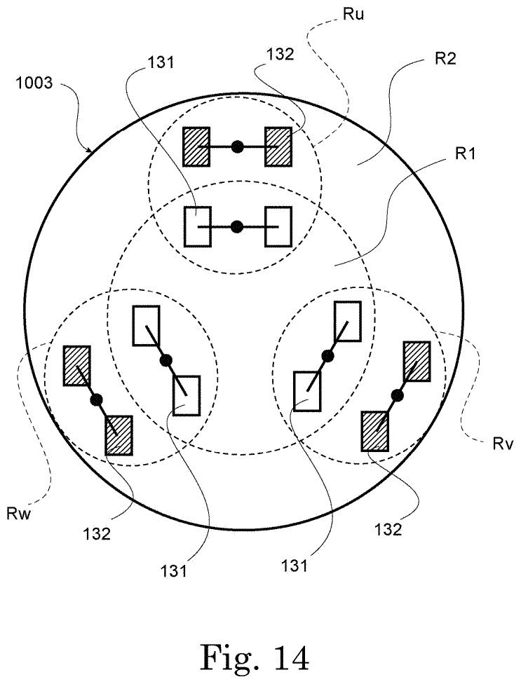

Also, in the example illustrated in FIG. 12, the U-phase switching elements 131 and 132 are collectively mounted on the area Ru for the U phase, the V-phase switching elements 131 and 132 are collectively mounted on the area Rv for the V phase, and the W-phase switching elements 131 and 132 are collectively mounted on the area Rw for the W phase. Then, the phases are in isotropic mounting arrangement to each other. FIG. 13 is a diagram schematically illustrating another example of the mounting areas of the switching elements 131 and 132 in the modification illustrated in FIG. 11.

Also in the example illustrated in FIG. 13, the first region R1 and the second region R2 are one region and the other region obtained by dividing the region on the substrate 1003 by a linear boundary. Also in the example illustrated in FIG. 13, the switching elements 131 and 132 of the respective UVW phases are collectively mounted for each phase in the three regions Ru, Rv, and Rw arranged along the boundary between the first region R1 and the second region R2. The low-heat generating switching element 131 and the high-heat generating switching element 132 are in a symmetrical mounting arrangement about the boundary between the first region R1 and the second region R2. Next, a modification in which the first region R1 and the second region R2 are formed without depending on a heat dissipation structure such as a sub-heat sink will be described.

FIG. 14 is a diagram illustrating an example of mounting arrangement of the switching elements 131 and 132 on the first region R1 and the second region R2 formed without depending on the heat dissipation structure.

The example illustrated in FIG. 14 includes, for example, the main heat sink described above, but does not include the sub-heat sink. In such a case, heat dissipation efficiency by the main heat sink is higher in the edge portion than in the central portion of the substrate 1003. That is, also in the modification illustrated in FIG. 14, as in the case illustrated in FIG. 9, one region obtained by dividing the region on the substrate 1003 into the central portion and the edge portion is the second region R2 having high heat dissipation, and the other region is the first region R1 having low heat dissipation, but the positions of the first region R1 and the second region R2 are opposite to those in the case illustrated in FIG. 9.

Therefore, the low-heat generating switching element 131 is mounted in first region R1 on the central portion side of the substrate 1003, and the high-heat generating switching element 132 is mounted in the second region R2 on the edge portion side of the substrate 1003.

In the example illustrated in FIG. 14, as in the case illustrated in FIG. 9, the low-heat generating switching element 131 is, for example, a switching element of the first inverter 101, and the high-heat generating switching element 132 is, for example, a switching element of the second inverter 102. In addition, the U-phase switching elements 131 and 132 are collectively mounted on the area Ru for the U phase, the V-phase switching elements 131 and 132 are collectively mounted on the area Rv for the V phase, and the W-phase switching elements 131 and 132 are collectively mounted on the area Rw for the W phase. Then, the phases are in isotropic mounting arrangement to each other.

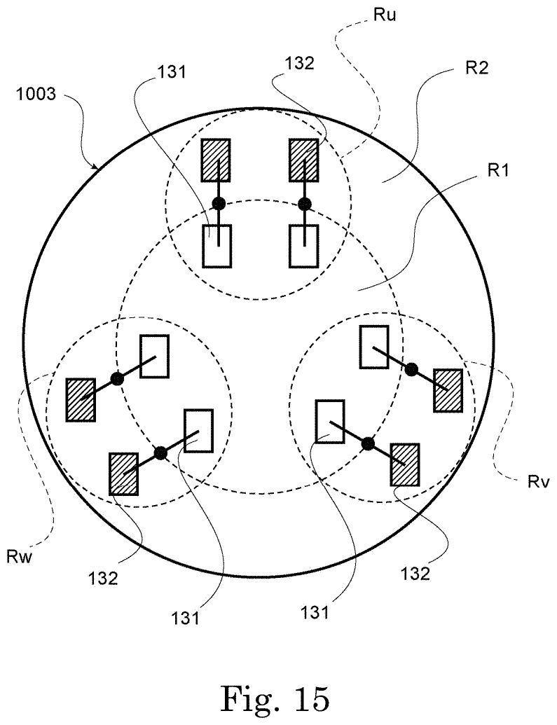

FIG. 15 is a diagram illustrating another example of the mounting arrangement of the switching elements 131 and 132 with respect to the first region R1 and the second region R2 formed without depending on the heat dissipation structure.

Also in the example illustrated in FIG. 15, for example, the main heat sink described above is provided but the sub-heat sink is not provided, and the heat dissipation efficiency by the main heat sink is higher in the edge portion than the central portion of the substrate 1003. The low-heat generating switching element 131 is mounted in the first region R1 on the central portion side of substrate 1003, and the high-heat generating switching element 132 is mounted in second region R2 on the edge portion side of substrate 1003.

In addition, the U-phase switching elements 131 and 132 are collectively mounted on the area Ru for the U phase, the V-phase switching elements 131 and 132 are collectively mounted on the area Rv for the V phase, and the W-phase switching elements 131 and 132 are collectively mounted on the area Rw for the W phase. Then, the phases are in isotropic mounting arrangement to each other.

In the example illustrated in FIG. 15, similarly to the modification illustrated in FIG. 11, the low-heat generating switching element 131 is, for example, a low-side switching element, and the high-heat generating switching element 132 is, for example, a high-side switching element.

In any of the modifications described above, high heat dissipation efficiency is achieved by mounting each of the switching elements 131 and 132 in the heat dissipation regions R1 and R2 according to the amount of heat generation. In addition, since the heat dissipation efficiency in the circuit on the substrate 1003 corresponding to a power converter is high, miniaturization and high output of the electromechanical motor corresponding to a drive are realized.

Vehicles such as automobiles are generally equipped with a power steering device. A power steering device generates an auxiliary torque for assisting the steering torque of the steering system generated by the driver operating the steering handle. The auxiliary torque is generated by the auxiliary torque mechanism, and the burden on the driver's operation can be reduced. For example, the auxiliary torque mechanism includes a steering torque sensor, an ECU, a motor, a reduction mechanism, and the like. The steering torque sensor detects the steering torque in the steering system. The ECU generates a drive signal based on the detection signal of the steering torque sensor. The motor generates an auxiliary torque according to the steering torque based on the drive signal, and transmits the auxiliary torque to the steering system via the reduction mechanism.

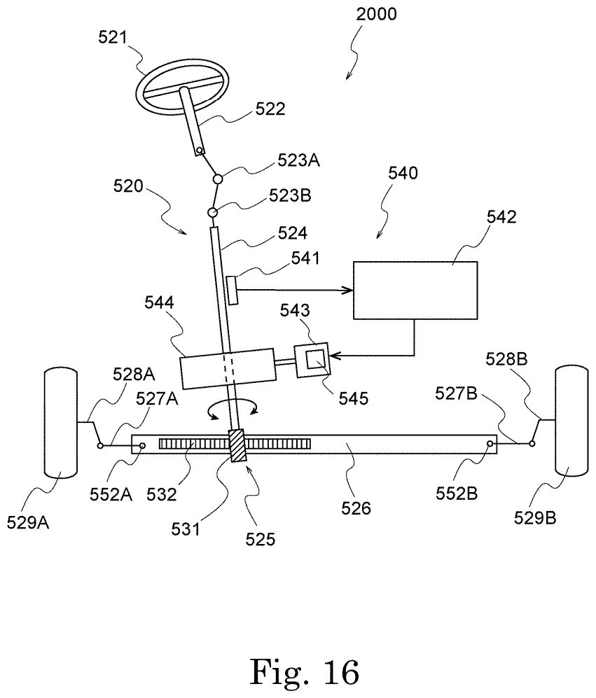

The motor drive assembly 1000 of the above example embodiment is suitably used for a power steering device. FIG. 16 is a diagram schematically illustrating the configuration of an electric power steering device 2000 according to the present example embodiment.

The electric power steering device 2000 includes a steering system 520 and an auxiliary torque mechanism 540.

The steering system 520 includes, for example, a steering handle 521, a steering shaft 522 (also referred to as a “steering column”), free shaft joints 523A and 523B, and a rotating shaft 524 (also referred to as a “pinion shaft” or “input shaft”).

The steering system 520 also includes, for example, a rack and pinion mechanism 525, a rack shaft 526, left and right ball joints 552A and 552B, tie rods 527A and 527B, knuckles 528A and 528B, and left and right steering wheels (for example, left and right front wheels) 529A and 529B.

The steering handle 521 is connected to the rotating shaft 524 via the steering shaft 522 and the free shaft joints 523A and 523B. The rack shaft 526 is connected to the rotating shaft 524 via the rack and pinion mechanism 525. The rack and pinion mechanism 525 has a pinion 531 provided to the rotating shaft 524 and a rack 532 provided to the rack shaft 526. The right steering wheel 529A is connected to the right end of the rack shaft 526 via the ball joint 552A, the tie rod 527A and the knuckle 528A in this order. Similar to the right side, the left steering wheel 529B is connected to the left end of the rack shaft 526 via the ball joint 552B, the tie rod 527B and the knuckle 528B in this order. Here, the right side and the left side correspond to the right side and the left side as seen from the driver sitting on the seat, respectively.

According to the steering system 520, steering torque is generated when the driver operates the steering handle 521, and is transmitted to the left and right steering wheels 529A and 529B via the rack and pinion mechanism 525. As a result, the driver can operate the left and right steering wheels 529A and 529B.

The auxiliary torque mechanism 540 includes, for example, a steering torque sensor 541, an ECU 542, a motor 543, a speed reduction mechanism 544, and a power supply device 545. The auxiliary torque mechanism 540 applies auxiliary torque to the steering system 520 from the steering handle 521 to the left and right steering wheels 529A and 529B. The auxiliary torque is sometimes referred to as “additional torque”.

As the ECU 542, for example, the control circuits 301 and 302 illustrated in FIG. 1 and elsewhere are used. Further, as the power supply device 545, for example, the inverters 101 and 102 illustrated in FIG. 1 and elsewhere are used. Further, as the motor 543, for example, the motor 200 illustrated in FIG. 1 and elsewhere is used. In a case where the ECU 542, the motor 543, and the power supply device 545 constitute a unit generally referred to as an “electromechanical motor”, the structures illustrated in FIGS. 7 and 8 are suitably employed.

Of the elements illustrated in FIG. 16, the mechanism configured of the elements excluding the ECU 542, the motor 543, and the power supply device 545 corresponds to an example of the power steering mechanism driven by the motor 543.

The steering torque sensor 541 detects the steering torque of the steering system 520 applied by the steering handle 521. The ECU 542 generates a drive signal for driving the motor 543 based on a detection signal from the steering torque sensor 541 (hereinafter, referred to as a “torque signal”). The motor 543 generates an auxiliary torque according to the steering torque based on the drive signal. The auxiliary torque is transmitted to the rotating shaft 524 of the steering system 520 via the speed reduction mechanism 544. The speed reduction mechanism 544 is, for example, a worm gear mechanism. Auxiliary torque is further transmitted from the rotating shaft 524 to the rack and pinion mechanism 525.

The power steering device 2000 is classified into a pinion assist type, a rack assist type, a column assist type, or the like, depending on the part where the auxiliary torque is applied to the steering system 520. FIG. 16 illustrates the power steering device 2000 of the pinion-assist type. However, the power steering device 2000 is also applied to the rack assist type, the column assist type, and the like.

Not only a torque signal but also a vehicle speed signal, for example, can be input to the ECU 542. The microcontroller of the ECU 542 can PWM-control the motor 543 based on a torque signal, a vehicle speed signal, or the like.

The ECU 542 sets a target current value at least based on the torque signal. It is preferable that the ECU 542 sets the target current value in consideration of the vehicle speed signal detected by the vehicle speed sensor and further in consideration of the rotation signal of the rotor detected by the angle sensor. The ECU 542 can control the drive signal of the motor 543, that is, the drive current so that the actual current value detected by the current sensor (see FIG. 1) matches the target current value.

According to the power steering device 2000, the left and right steering wheels 529A and 529B can be operated by the rack shaft 526 by utilizing the combined torque obtained by adding the auxiliary torque of the motor 543 to the steering torque of the driver. In particular, by using the motor drive assembly 1000 of the above example embodiment, it is possible to realize downsizing and an increase in the power output of the motor drive assembly 1000, and to realize space saving and stabilization of assist power in the power steering apparatus 2000.

Note that, in an example used in the above description, power is supplied to the motor in which the windings of each phase are not connected to each other by the inverter connected to both ends of the windings. However, in the power converter and the drive of the present disclosure, power may be supplied to the motor by, for example, a single inverter, or power may be supplied to, for example, a double star motor. In the case of supplying power to a double-star motor, for example, a high-heat generating switching element may supply power to one of the double stars, and a low-heat generating switching element may supply power to the other of the double stars.

Further, in the above description, a power steering device is mentioned as an example of the usage in the power converter and the drive of the present disclosure. However, the usage of the power converter and the drive of the present disclosure is not limited to those described above. They are applicable to a wide range including a pump and a compressor.

The above-described example embodiments are to be considered in all respects as illustrative and not restrictive. The scope of the present disclosure is shown not by the above-described example embodiment but by the scope of the claims, and is intended to include all changes within the meaning and scope equivalent to the scope of claims.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1-13. (canceled)

14: A power converter that converts power from a power source and supplies converted power to a motor, the power converter comprising:
an inverter connected to a winding of the motor and including switches that generate heat along with power control operation; and
a substrate on which the switches are mounted; wherein
a first switch of the switches is mounted in a first region on the substrate, and a second switch that generates more heat than the first switch is mounted in a second region having a higher heat dissipation than a heat dissipation of the first region.

15: The power converter according to claim 14, wherein
the second switch performs switching by Pulse Width Modulation (PWM) control; and
the first switch maintains one of an on state and an off state during a time in which the second switch performs switching operation a plurality of times.

16: The power converter according to claim 15, wherein
the inverter includes a first inverter connected to one end of a winding of the motor and a second inverter connected to another end with respect to the one end; and
the first switch is connected to the second switch via the winding, and a current is controlled by switching of the second switch flows.

17: The power converter according to claim 14, wherein
the inverter includes a first inverter connected to one end of a winding of the motor and a second inverter connected to another end with respect to the one end; and
the first switch is provided to one of the first inverter and the second inverter, and the second switch is provided to another of the first inverter and the second inverter.

18: The power converter according to claim 14, wherein
the inverter includes a high-side switch connected to the winding and a power supply end and a low-side switch connected to the winding and a ground end; and
the first switch is one of the high-side switch and the low-side switch, and the second switch is another of the high-side switch and the low-side switch.

19: The power converter according to claim 14, further comprising an entire heat sink that directly or indirectly contacts both the first switch and the second switch to dissipate heat.

20: The power converter according to claim 14, wherein a heat dissipation structure that promotes more heat dissipation in the second region than heat dissipation in the first region is provided inside or outside of the substrate.

21: The power converter according to claim 20, further comprising a portion of a heat sink that directly or indirectly contacts the switch mounted in the second region to promote more heat dissipation in the second region than heat dissipation in the first region.

22: The power converter according to claim 14, wherein the first region and the second region define one region and another region obtained by dividing a region on the substrate with a linear boundary.

23: The power converter according to claim 14, wherein the first region and the second region define one region and another region obtained by dividing a region on the substrate into a central portion and an edge portion.

24: A drive comprising:
the power converter according to claim 14; and
a motor to which power converted by the power converter is supplied.

25: The drive according to claim 24, wherein at least one of a housing that houses the motor and a holder of a bearing that holds a rotation shaft of the motor also defines and functions as a heat sink that directly or indirectly contacts the switches to dissipate heat.

26: A power steering device comprising:
the power converter according to claim 14;
a motor to which power converted by the power converter is supplied; and
a power steering mechanism that is driven by the motor.
